(19) United States
(12) Patent Application Publication
(10) Pub. No.: US 2026/0068747 A1
(43) Pub. Date: Mar. 5, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chien-Fu Tseng, Taipei City (TW); Han-Yi Lu, Hsinchu City (TW); Wei-Cheng Wu, Hsinchu City (TW); Der-Chyang Yeh, Hsin-Chu (TW)

(73) Assignee: Taiwan Semiconductor Manufacturing Company, Ltd., Hsinchu (TW)

(21) Appl. No.: 18/823,594

(22) Filed: Sep. 3, 2024

(51) Int. Cl. H01L 23/10; H01L 21/56; H01L 23/00; H01L 23/31; H01L 25/065

(52) U.S. Cl. CPC H01L 23/10

(57) ABSTRACT

A semiconductor device includes a first semiconductor die, a second semiconductor die bonded to the first semiconductor die, a sealing layer, and an encapsulant disposed on the first semiconductor die and laterally covering the sealing layer and the second semiconductor die. The second semiconductor die is bent with an edge of the second semiconductor die curving upwardly, where a non-bond area is at a periphery of a bonding interface of the first and second semiconductor dies. The sealing layer seals the non-bond area of the first and second semiconductor dies.

### BACKGROUND

As semiconductor technologies further advance, stacked and bonded semiconductor devices have emerged as an effective alternative to further reduce the physical size of a semiconductor device. In a stacked semiconductor device, active circuits such as logic, memory, processor circuits and the like are fabricated at least partially on separate substrates and then physically and electrically bonded together in order to form a functional device. Such bonding processes utilize sophisticated techniques, and improvements are desired. Although existing semiconductor devices and manufacturing method thereof have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are schematic cross-sectional views of various stages of a bonded structure, in accordance with some embodiments.

FIGS. 2A-2C are schematic cross-sectional views of various stages of a bonded structure, in accordance with alternative embodiments.

FIGS. 3A-3C are schematic top views illustrating various configurations of the bonded structure, in accordance with some embodiments.

FIGS. 4A-4D are schematic cross-sectional views of various stages of manufacturing a semiconductor device, in accordance with some embodiments.

FIGS. 5A-5B are schematic cross-sectional views of various stages of manufacturing a semiconductor device, in accordance with alternative embodiments.

FIGS. 5C-5E are schematic top views illustrating various configurations of the structure shown in FIG. 5A, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will be described with respect to specific embodiments in which semiconductor devices within a system on integrated circuit (SoIC) utilize a sealing layer which extends into the respective bonding structures of the individual dies and seals the non-bond areas of the bonded die structure. However, the embodiments illustrated herein are only intended to be illustrative of the embodiments and are not intended to limiting. Rather, the ideas presented herein may be incorporated into a wide variety of embodiments, and all such embodiments are fully intended to be included within the scope of the embodiments.

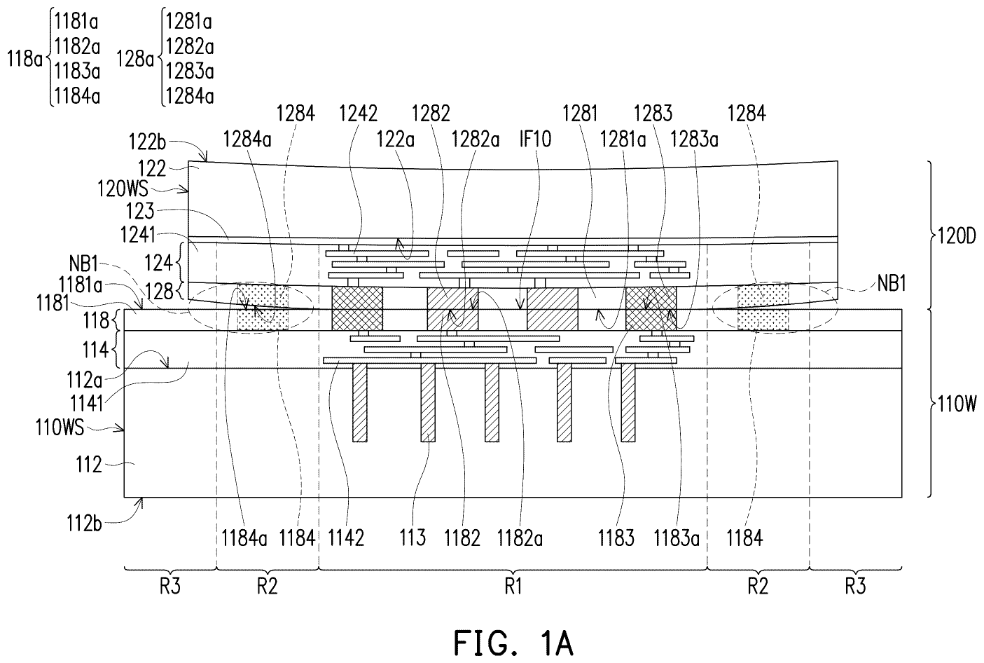

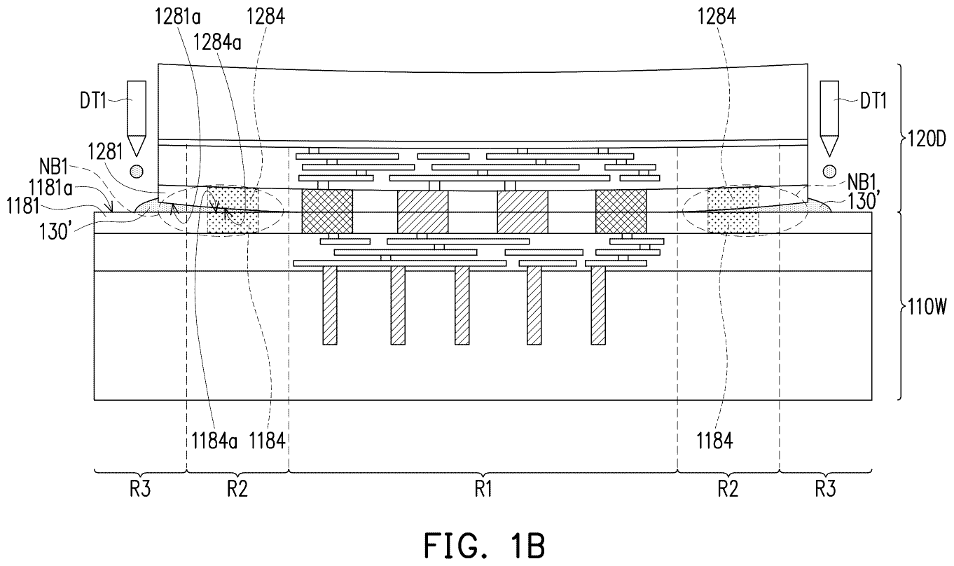

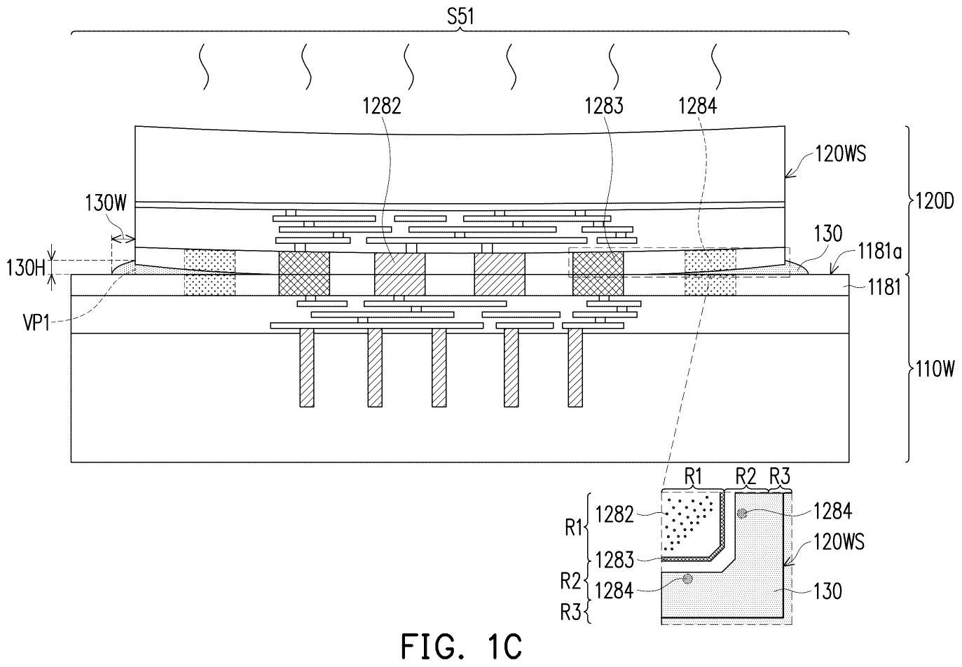

FIGS. 1A-1C are schematic cross-sectional views of various stages of a bonded structure, in accordance with some embodiments. Referring to FIG. 1A, a semiconductor die 120D may be disposed on and bonded to a semiconductor wafer 110W. Although only one semiconductor die 120D is shown, it should be appreciated that more than one semiconductor dies 120 may be bonded to the semiconductor wafer 110W. For example, the semiconductor wafer 110W includes a plurality of die regions, and each of the semiconductor dies 120D is bonded to one of the die regions of the semiconductor wafer 110W. In some embodiments, the semiconductor wafer 110W includes a first semiconductor substrate 112, which includes a semiconductor material such as silicon, doped or undoped, or an active layer of a semiconductor-on-insulator (SOI) substrate. The first semiconductor substrate 112 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may be used.

With continued reference to FIG. 1A, the first semiconductor substrate 112 may have a first surface (e.g., a front surface or an active surface) 112a and a second surface (e.g., a rear surface) 112b opposite to the first surface 112a. Devices (not individually shown) may be formed in and/or on the first surface 112a of the first semiconductor substrate 112. For example, the devices include active devices (e.g., transistors, diodes, etc.), passive devices (e.g., capacitors, resistors, inductors, etc.), a combination thereof, or the like. In alternative embodiments, the semiconductor wafer 110W is free of active and/or passive devices. The semiconductor wafer 110W may include a first interconnect structure 114 formed over the first surface 112a of the first semiconductor substrate 112. For example, the first interconnect structure 114 includes one or more dielectric layer(s) 1141 and respective metallization pattern(s) 1142 (e.g., metal lines, metal vias, metal pads, etc.). The metallization patterns 1142 may be embedded in the dielectric layers 1141 and electrically coupled to the devices (if present) to form functional circuits.

With continued reference to FIG. 1A, the dielectric layer 1141 of the first interconnect structure 114 may be the inter-metallization dielectric (IMD) layer which is formed of a dielectric material such as undoped silicate glass (USG), phosphosilicate glass (PSG), borophosphosilicate glass (BPSG), fluorosilicate glass (FSG), spin-on-glass, silicon oxide, silicon nitride, silicon carbide, silicon oxynitride, compounds thereof, composites thereof, combinations thereof, and/or the like. The metallization pattern 1142 may route electrical signals by using vias and/or lines. The material(s) of the metallization patterns 1142 may include tungsten, cobalt, nickel, copper, silver, gold, aluminum, the like, or combinations thereof. In some embodiments, the semiconductor wafer 110W includes through substrate vias (TSVs) 113 formed in the first semiconductor substrate 112 and extending into the dielectric layers 1141 to be in physical and electrical contact with the metallization pattern 1142.

With continued reference to FIG. 1A, the semiconductor wafer 110W may include a first bonding structure 118 formed over the first interconnect structure 114. For example, the first bonding structure 118 includes a bonding dielectric layer 1181 which may be or may include silicon oxide, silicon nitride, silicon oxynitride, or the like. The first bonding structure 118 may include first bonding connectors 1182 distributed within a functional region R1 and laterally covered by the bonding dielectric layer 1181. The first bonding connectors 1182 may be electrically coupled to the metallization patterns 1142 of the first interconnect structure 114. In some embodiments, the first bonding structure 118 includes at least one second bonding connector 1183 laterally covered by the bonding dielectric layer 1181 and located within the functional region R1. For example, the second bonding connector 1183 is a seal ring disposed at the periphery of the functional region R1 and encircling the array of the first bonding connectors 1182. In some embodiments, the first bonding structure 118 includes at least one dummy bonding connector 1184 located within a buffer region R2, where the buffer region R2 is connected to and encircles the functional region R1. A peripheral region R3 may be connected to the buffer region R2 and between the sidewall 110WS of the semiconductor wafer 110W and the buffer region R2. Alternatively, the dummy bonding connectors 1184 are omitted, and thus the dummy bonding connectors 1184 are outlined in the dashed lines. It is appreciated that the number of the first and second bonding connectors and the number of the dummy bonding connectors shown herein are examples and construed no limitation in the disclosure.

With continued reference to FIG. 1A, the first bonding connectors 1182 may be formed of a metal (e.g., copper, a copper alloy, or other suitable conductive material(s)) that facilitates the subsequent metal-to-metal bonding. The second bonding connectors 1183 and/or the dummy bonding connectors 1184 may be made of the material same as or similar to that of the first bonding connectors 1182. In some embodiments, the respective first bonding connector 1182 is a bonding pad. Alternatively, the respective first bonding connector 1182 may be a bonding via, a combination of a bonding pad and a bonding via, etc. The second bonding connectors 1183 and/or the dummy bonding connectors 1184 may have the same profile as or similar profiles to that of the first bonding connectors 1182. In some embodiments, the top surfaces 1182a of the first bonding connectors 1182, the top surfaces 1183a of the second bonding connectors 1183, and the top surfaces 1184a of the dummy bonding connectors 1184 are substantially leveled (or coplanar) with a top surface 1181a of the bonding dielectric layer 1181, within process variations. In some embodiments, the top surface of the first bonding structure 118 including the top surfaces (1181a, 1182a, 1183a, and 1184a) is viewed as a bonding surface 118a of the semiconductor wafer 110W. It is appreciated that the aforementioned examples are provided for illustrative purposes, and the semiconductor wafer 110W may include other elements for a given application.

With continued reference to FIG. 1A, the semiconductor die 120D may be formed in a semiconductor wafer (not shown), which may include different die regions that are singulated to form a plurality of the semiconductor dies 120D. The semiconductor die 120D may be a logic die (e.g., central processing unit (CPU), graphics processing unit (GPU), system-on-a-chip (SoC), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. The semiconductor die 120D may perform the same function as or a different function than the semiconductor wafer 110W.

The semiconductor die 120D may include a second semiconductor substrate 122 having an active surface 122a and a rear surface 122b opposite to each other. For example, the second semiconductor substrate 122 is made of the material same as or similar to the material of the first semiconductor substrate 112. The semiconductor die 120D may include a device layer 123 in which active/passive devices (e.g., transistors, capacitors, resistors, diodes, and the like) may be included. The device layer 123 may be formed at the active surface 122a of the second semiconductor substrate 122. The semiconductor die 120D may include a second interconnect structure 124 formed over the device layer 123. For example, the second interconnect structure 124 includes one or more dielectric layer(s) 1241 and metallization patterns 1242 embedded in the dielectric layer 1241 and electrically coupled to the device layer 123. In some embodiments, the metallization patterns 1242 is viewed as an interconnecting circuitry of the semiconductor die 120D. The materials of the dielectric layer 1241 and the metallization patterns 1242 of the second interconnect structure 124 may be the same as or similar to those of the dielectric layer 1141 and the metallization patterns 1142 of the first interconnect structure 114, respectively.

With continued reference to FIG. 1A, the semiconductor die 120D may include a second bonding structure 128 formed over the second interconnect structure 124. For example, the second bonding structure 128 includes a bonding dielectric layer 1281 which may be or may include silicon oxide, silicon nitride, silicon oxynitride, or the like. The second bonding structure 118 may include first bonding connectors 1282 distributed within the functional region R1 and laterally covered by the bonding dielectric layer 1281. The first bonding connectors 1282 may be electrically coupled to the device layer 123 through the metallization patterns 1242 of the second interconnect structure 124. In some embodiments, the second bonding structure 128 includes at least one second bonding connector 1283 laterally covered by the bonding dielectric layer 1281 and located within the functional region R1. For example, the second bonding connector 1283 is a seal ring disposed at the periphery of the functional region R1 and encircling the first bonding connectors 1282. In some embodiments, the second bonding structure 118 includes at least one dummy bonding connector 1284 located within the buffer region R2, where the buffer region R2 is between the edge (or sidewall) 120WS of the semiconductor die 120 and the functional region R1. Alternatively, the dummy bonding connectors 1284 are omitted, and thus the dummy bonding connectors 1284 are outlined in the dashed lines. It is appreciated that the number of the first and second bonding connectors and the number of the dummy bonding connectors shown herein are examples and construed no limitation in the disclosure.

With continued reference to FIG. 1A, the first bonding connectors 1282 may be formed of a metal (e.g., copper, a copper alloy, or other suitable conductive material(s)) that facilitates the subsequent metal-to-metal bonding. The second bonding connectors 1283 and/or the dummy bonding connectors 1284 may be made of the material same as or similar to that of the first bonding connectors 1282. In some embodiments, the respective first bonding connector 1282 is a bonding pad. Alternatively, the respective first bonding connector 1282 may include a bonding via, a combination of a bonding pad and a bonding via, etc. The second bonding connectors 1283 and/or the dummy bonding connectors 1284 may have the same profile as or similar profiles to that of the first bonding connectors 1282. In some embodiments, the top surfaces 1282a of the first bonding connectors 1282, the top surfaces 1283a of the second bonding connectors 1283 are substantially leveled (or coplanar) with a top surface 1281a of the bonding dielectric layer 1281, within process variations. The top surfaces 1284a of the dummy bonding connectors 1284 may (or may not be) leveled (or coplanar) with the top surfaces (1282a and 1283a) of the first and second bonding connectors (1282 and 1283). In some embodiments, the top surface of the second bonding structure 128 including the top surfaces (1281a, 1282a, 1283a, and 1284a) is viewed as a bonding surface 128a of the semiconductor die 120D. It is appreciated that the aforementioned examples are provided for illustrative purposes, and the semiconductor die 120D may include other elements for a given application.

With continued reference to FIG. 1A, the semiconductor die 120D and the semiconductor wafer 110W may be separately fabricated, and then the semiconductor die 120D may be positioned at the predetermined location of the semiconductor wafer 110W. Next, a bonding process may be performed on the semiconductor die 120D and the semiconductor wafer 110W. For example, the semiconductor die 120D and the semiconductor wafer 110W are bonded together in a face-to-face manner. For example, the active surface 122a of the semiconductor die 120D faces the first surface 112a of the semiconductor wafer 110W, and the second bonding structure 128 of the semiconductor die 120D is bonded to the first bonding structure 118 of the semiconductor wafer 110W. The bonding process may include dielectric-to-dielectric bonding (e.g., oxide-to-oxide bonding), metal-to-metal bonding (e.g., copper-to-copper bonding), metal-to-dielectric bonding (e.g., copper-to-oxide bonding), any combinations thereof, and/or the like.

In some embodiments, to facilitate the bonding process, surface preparation for the bonding surface 118a of the semiconductor wafer 110W and the bonding surface 128a of the semiconductor die 120D is performed to remove particles thereon. The surface preparation may include surface cleaning and activation or other suitable process. In some embodiments, at least the top surfaces (1182a and 1282a) of the first bonding connectors (1182 and 1282), the top surfaces (1183a and 1283a) of the second bonding connectors (1183 and 1283), and the top surfaces (1184a and 1284a) of the dummy bonding connectors (1184 and 1284) are cleaned before performing the bonding process. For example, not only particles are removed, but also native oxides formed on the top surfaces of these bonding connectors are removed by wet cleaning. After the cleaning, activation of the top surface (1181a and 1281a) of the bonding dielectric layer (1181 and 1281) may be performed for development of high bonding strength.

With continued reference to FIG. 1A, the semiconductor die 120D may be aligned with the semiconductor wafer 110W and sub-micron alignment precision may be achieved. Once the semiconductor die 120D and the semiconductor wafer 110W are aligned, the semiconductor die 120D and the semiconductor wafer 110W may be placed on and in contact with one another. When the activated top surface 1281a of the bonding dielectric layer 1281 is in contact with the activated top surface 1181a of the bonding dielectric layer 1181, the bonding dielectric layer 1281 of the semiconductor die 120D and the bonding dielectric layer 1181 of the semiconductor wafer 110W may be pre-bonded. After pre-bonding the semiconductor die 120D to the semiconductor wafer 110W, the bonding of the semiconductor die 120D and the semiconductor wafer 110W may be performed to form a bonding interface IF10 of the bonded structure. In some embodiments, a thermal annealing process is performed to facilitate the bonding between the bonding connectors. During the thermal annealing process, metal diffusion and grain growth may occur at the bonding interface IF10 at least between the first bonding connectors (1282 and 1182) and the second bonding connectors (1283 and 1183). After the bonding of the semiconductor die 120D and the semiconductor wafer 110W is complete, the first bonding connectors (1282 and 1182) may provide vertical electrical connections between the semiconductor die 120D and the semiconductor wafer 110W.

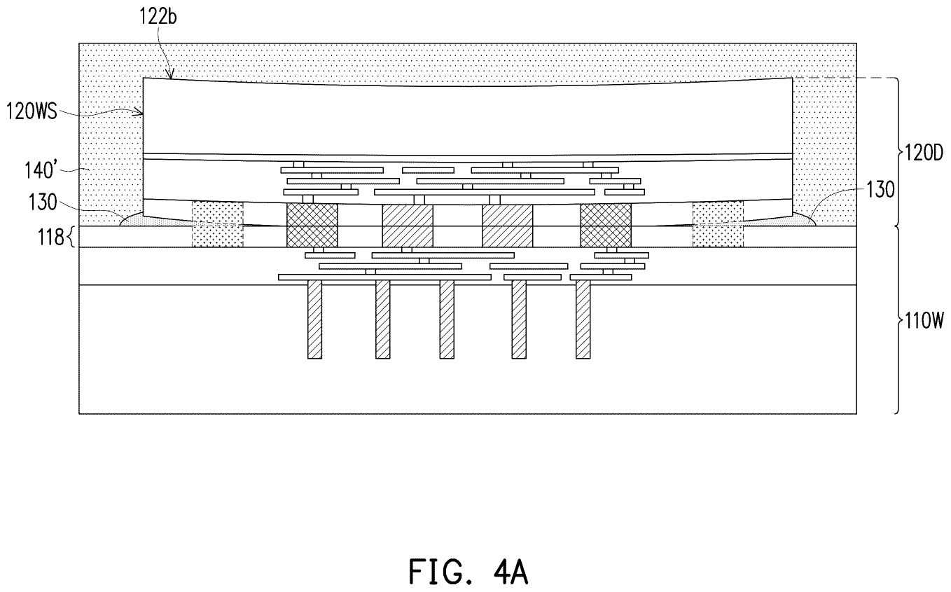

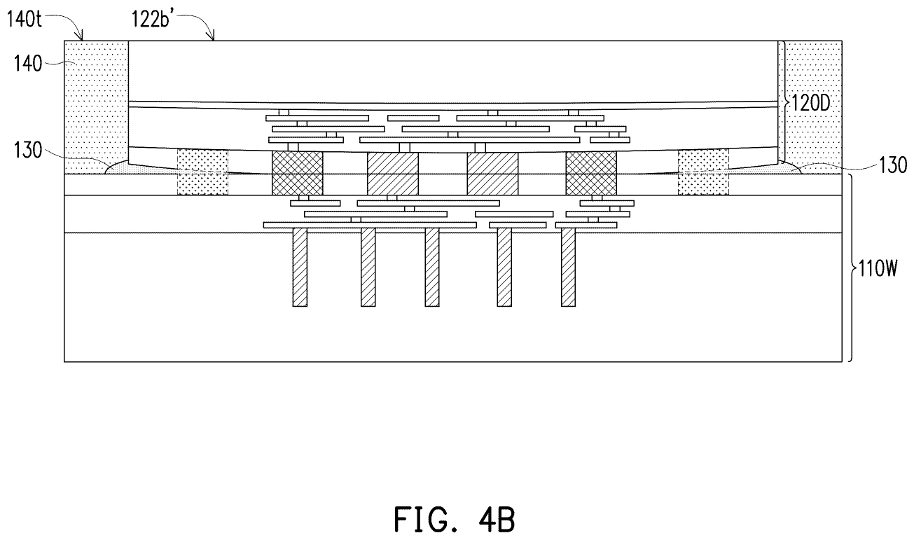

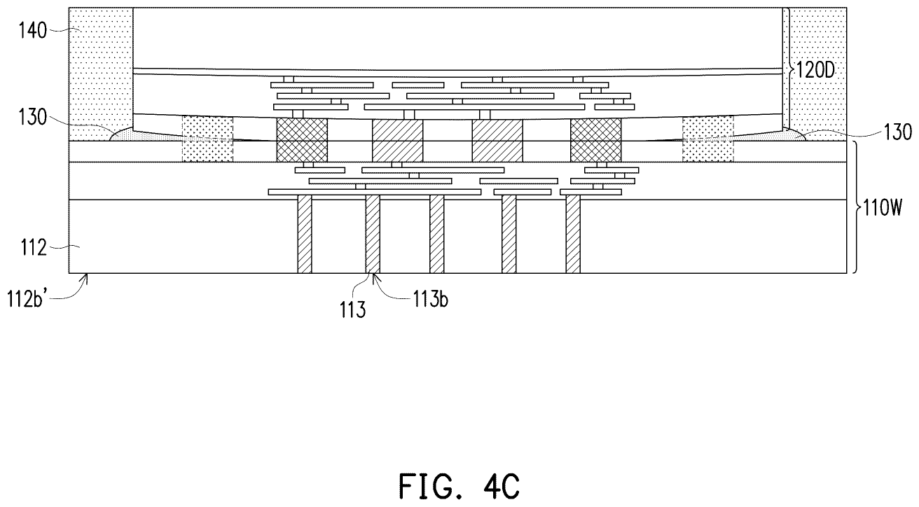

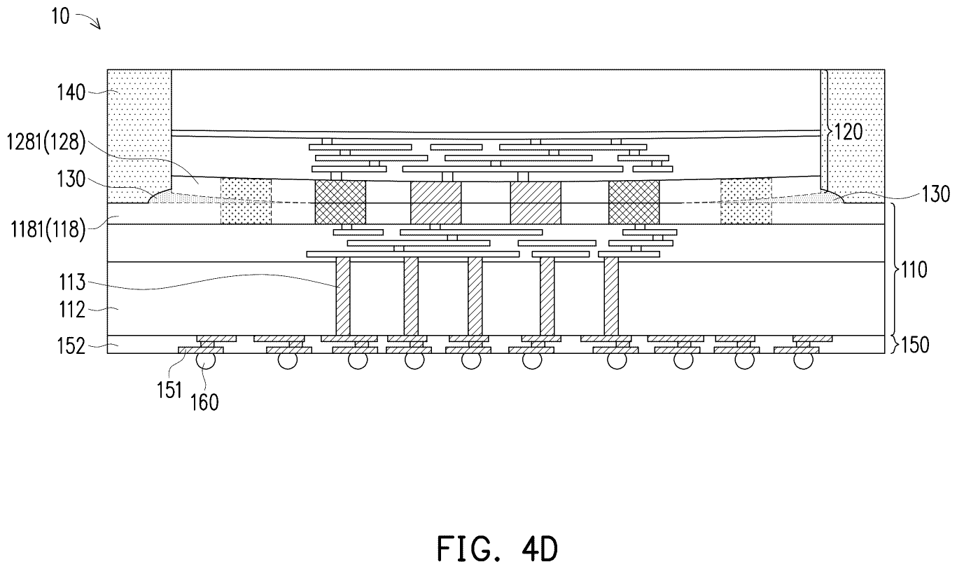

Still referring to FIG. 1A, the semiconductor die 120D may warp (or is bent) with the edges 120WS (or a periphery) curving upwardly, where the functional region R1 of the semiconductor die 120D is lower than the periphery of the semiconductor die 120D. The bonding surface 128a of the semiconductor die 120D may present a concave curve in the cross-sectional view, resulting in the first bonding connectors 1282 in the functional region R1 being lower than the dummy bonding connectors 1284 in the buffer region R2. After the bonding process, non-bond areas NB1 may exist at the bonding interface IF10, for example, in the peripheral region R3 (or both of the buffer region R2 and the peripheral region R3). During subsequent processing steps (e.g., the formation of an encapsulant described in FIGS. 4A-4B), the large coefficient of thermal expansion (CTE) mismatch among the encapsulant, the semiconductor die, and the semiconductor wafer may generate stress in the resulting structure, especially at the interface between the encapsulant and the semiconductor die/the semiconductor wafer. Under the thermal mismatch stresses, the non-bond areas NB1 may be enlarged and cracks (if exist) may extend toward the functional region R1. This may result in the semiconductor die 110D separated from the semiconductor wafer 110W and may render the resulting structure to be non-functional or failure. Thus, in the manufacture of the semiconductor device, it is important to prevent the bonding interface of the semiconductor die 120D and the semiconductor wafer 110W from delaminating and prevent any cracks extending into the functional region R1. As described in greater detail below, by forming a sealing layer to seal the bonded structure, the adhesion of the bonded structure may be improved and the bonding interface stress during the formation of the encapsulant may be reduced.

Referring to FIG. 1B with reference to FIG. 1A, a polymeric material layer 130′ may be formed on the first bonding structure 118 of the semiconductor wafer 110W. In some embodiments, the polymeric material layer 130′ is in a liquid state when selectively dispensed over the first bonding structure 118 using any suitable dispensing tool DT1 or method (e.g., jetting, dispensing, etc.). The polymeric material layer 130′ may flow from the peripheral region R3 toward the buffer region R2. In some embodiments, the polymeric material layer 130′ fills the non-bond areas NB1 of the bonded structure by capillarity. For example, the polymeric material layer 130′ is between portions of the bonding dielectric layer 1281 and the bonding dielectric layer 1181 which are not fused together, and the polymeric material layer 130′ is in physical contact with the portions of the top surfaces (1281a and the 1181a) of the bonding dielectric layers (1281 and 1181). In some embodiments, the polymeric material layer 130′ spreads to be between the dummy bonding connector 1284 and the dummy bonding connector 1184 which are in the non-bond areas NB1 and not directly bonded together, and the polymeric material layer 130′ is in physical contact with the top surfaces (1284a and 1184a) of the dummy bonding connectors (1284 and 1184).

With continued reference to FIG. 1B, the polymeric material layer 130′ may be an inorganic polymer. In some embodiments, the polymeric material layer 130′ includes a polysilazane-based dielectric material including Si—N bonds, Si—H bonds, N—H bonds, or the like. The polysilazane-based dielectric material may have a basic structure composed of silicon (Si) and nitrogen (N) atoms in an alternating sequence, where each Si atom may be bound to two N atoms, or each N atom may be bound to two Si atoms. For example, the polymeric material layer 130′ includes perhydropolysilazane (PHPS). The polymeric material layer 130′ may include a formula (—(SiH₂NH)ₙ—) and may be converted to silicon oxide in the subsequent steps. The polymeric material layer 130′ may be referred to as a precursor according to some embodiments. In some embodiments, the PHPS is dissolved in a compatible solvent (e.g., dibutyl ether (DBE) or the like). The concentration of the PHPS in solution may be varied to adjust the consistency (i.e., viscosity) of the solution and thickness of the dispensing. In some embodiments, the solution containing about 20% by weight of the PHPS is used. It is realized that the value is an example and may be changed to other suitable values depending on process requirements.

Referring to FIG. 1C with reference to FIG. 1B, a thermal treatment S51 may be performed on the polymeric material layer 130′ to form a sealing layer 130. For example, the thermal treatment S51 includes an annealing process conducted with a temperature in the range from about 250° C. to about 320° C., and the annealing duration in the range from about less than 10 hours. During the thermal treatment S51, un-desired element(s), such as solvent, may be removed to form the sealing layer 130. The thermal treatment S51 may enhance quality of the polymeric material layer 130′ through a mechanism of solvent out-diffusion and cross-linking. In some embodiments, the thermal treatment S51 enables conversion of the polymeric material layer 130′ to be the sealing layer 130 as a solid and stable layer. In some embodiments, in addition to converting and solidifying the polymeric material layer 130′, the thermal treatment S51 has the function of densifying and improving the mechanical property of the sealing layer 130. In the embodiment where the polymeric material layer 130′ includes a PHPS, the thermal treatment S51 converts the PHPS to silicon oxide. A chemical reaction equation may be expressed as: SiH₂NH+2H₂O→SiO₂+NH₃+2H₂. The reaction may result in silicon oxide (SiO₂), ammonia (NH₃), and hydrogen (H₂), where ammonia and hydrogen are gaseous, and hence only silicon oxide is left and seals the bonded structure. In some embodiments where PHPS is not completely hydrolyzed, a portion of the PHPS closed to the functional region is left and the other portion of the PHPS is converted to silicon oxide.

With continued reference to the enlarged view in FIG. 1C, the sealing layer 130 may spread from the peripheral region R3 and extend into the buffer region R2. The sealing layer 130 may stop in the buffer region R2 without extending into the functional region R1. For example, the sealing layer 130 covers the dummy bonding connectors 1284 located in the buffer region R2, but does not extend to be in contact with the second bonding connectors 1283 (e.g., the seal ring). In some embodiments, the edges 120WS of the semiconductor die 120D are covered by the sealing layer 130. In the cross-sectional view, the sealing layer 130 may have a convex curved surface connecting the sidewall 120WS of the semiconductor die 120 and the top surface 1181a of the bonding dielectric layer 1181 of the semiconductor wafer 110W. For example, the sealing layer 130 climbs upward to cover the sidewall 120WS of the semiconductor die 120D by a non-zero height 130H. The lateral dimension 130W (e.g., the width) of the sealing layer 130 measured from the boundary of the sealing layer 130 to the virtual plane VP1 on which the sidewall 120WS of the semiconductor die 120D is located may be non-zero. The coverage area of the sealing layer 130 on the bonding surface of the semiconductor wafer 110W may be greater than the coverage area of the sealing layer 130 on the sidewall 120WS of the semiconductor die 120D. In some embodiments, the lateral dimension 130W is greater than the height 130H. For example, a ratio of the lateral dimension 130W to the height 130H is about 3:1. It is realized that the ratio is an example and may be changed to other suitable values depending on product requirements.

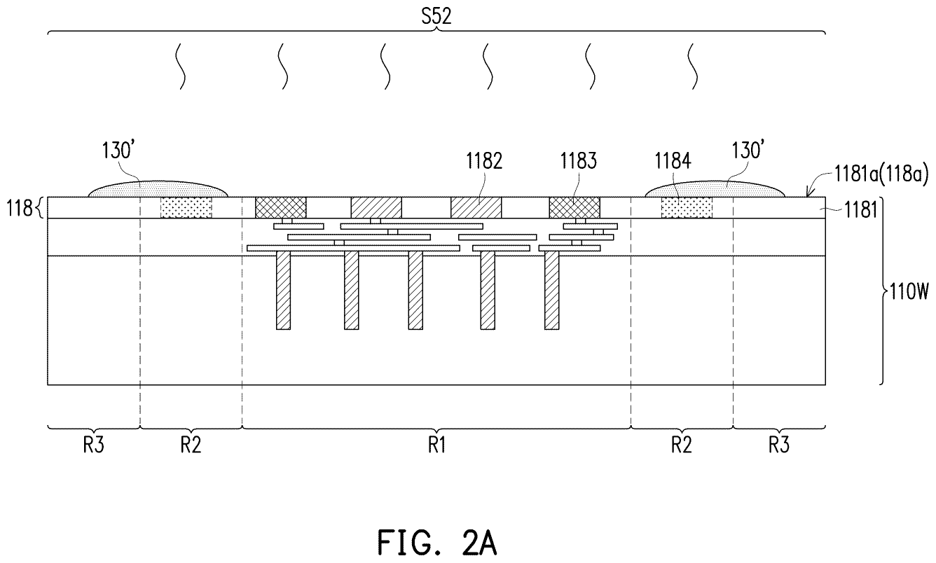

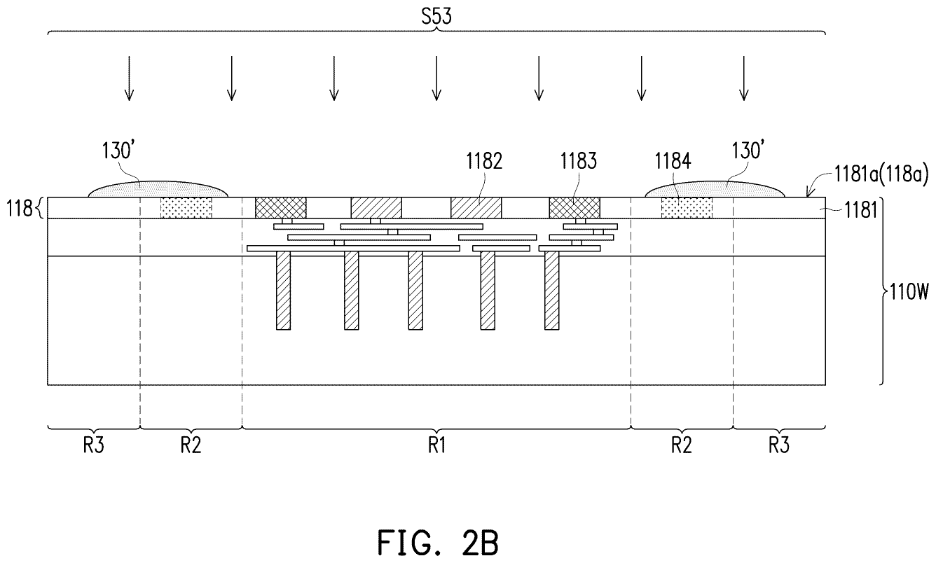

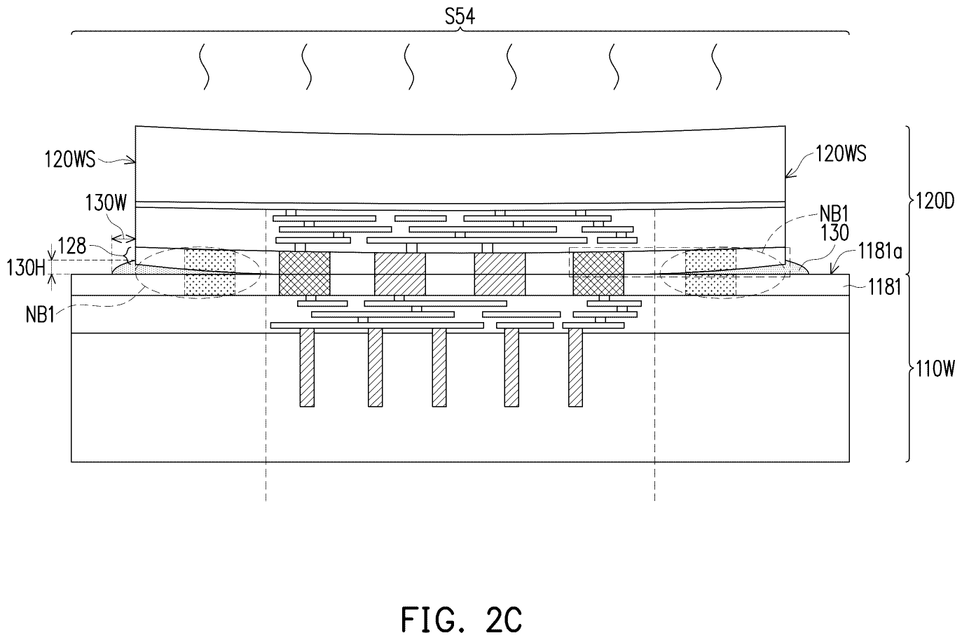

FIGS. 2A-2C are schematic cross-sectional views of various stages of a bonded structure, in accordance with alternative embodiments. Unless explicitly stated otherwise, the materials and the formation methods of the components in these embodiments are essentially the same as the like components, which are denoted by like reference numerals in the embodiments described in accompanying with FIGS. 1A-1C.

Referring to FIG. 2A, the semiconductor wafer 110W may be provided, and the polymeric material layer 130′ may be formed on the semiconductor wafer 110W. For example, the polymeric material layer 130′ is selectively dispensed over the first bonding structure 118. The material and the forming method of the polymeric material layer 130′ may be similar to those of the polymeric material layer 130′ described in FIG. 1B, and thus the detailed descriptions are not repeated for simplicity. In some embodiments, a first thermal treatment S52 is performed on the polymeric material layer 130′. For example, the first thermal treatment S52 includes a baking process conducted with a temperature in the range from about 100° C. to about 150° C., and the baking duration in the range from about 5 minutes to about 10 minutes. During the first thermal treatment S52, un-desired element(s), such as solvent, may be removed from the polymeric material layer 130′. In some embodiments, the first thermal treatment S52 is viewed as the solvent volatilization process.

In some embodiments, the polymeric material layer 130′ spreads from the peripheral region R3 toward the buffer region R2. The polymeric material layer 130′ may stop in the buffer region R2 without extending into the functional region R1. In some embodiments, the polymeric material layer 130′ covers the dummy bonding connectors 1184 and a portion of the bonding dielectric layer 1181 located within the buffer region R2 and the peripheral region R3, but the polymeric material layer 130′ does not cover the second bonding connectors 1183 (e.g., the seal ring) and the first bonding connectors 1182. The area covered by the polymeric material layer 130′ may correspond to the non-bond areas NB1 (see FIG. 1B). For example, the area(s) covered by the polymeric material layer 130′ is determined based on the simulation results and/or empirical data.

Referring to FIG. 2B, a plasma treatment S53 may be performed on the polymeric material layer 130′. In some embodiments, the process gas used in the plasma treatment S53 contains nitrogen gas. During the plasma treatment S53, nitrogen gas and water vapor may be released, so that the polymeric material layer 130′ may undergo hydrolysis reaction. The hydrolysis reaction may occur at room temperature (e.g., about 22° C. to about 24° C.). By performing the plasma treatment S53, dangling bonds may be formed at portions in the polymeric material layer 130′ (e.g., the polysilazane-based dielectric material) to be hydrolyzed. The plasma treatment S53 may activate reaction sites of the polymeric material layer 130′ and may be used as part of a process for generating the sealing layer 130 or to activate dangling bonds on the polymeric material layer 130′. For example, some Si—H bonds and/or Si—N bonds are broken to form dangling bonds. When the subsequent process is performed, hydroxyl (OH) groups may be bonded to the dangling bonds to form Si—OH bonds, and the OH groups may be crosslinked to form Si—O—Si bonds. The Si—N bonds in the polymeric material layer 130′ (e.g., the polysilazane-based dielectric material) may be replaced by oxygen atoms (O) to form silicon oxide. By performing the plasma treatment S53 on the polymeric material layer 130′ before the bonding process, the polymeric material layer 130′ may be completely (or mostly) hydrolyzed and converted to silicon oxide. Alternatively, the plasma treatment S53 is omitted.

Referring to FIG. 2C, the semiconductor die 120D may be picked and placed on the semiconductor wafer 110W. The semiconductor die 120D may be similar to the semiconductor die 120D described in FIG. 1A, and thus the detailed descriptions are not repeated herein. Next, the bonding process may be performed to bond the second bonding structure 128 of the semiconductor die 120D to the first bonding structure 118 of the semiconductor wafer 110W. The polymeric material layer 130′ may be interposed between the semiconductor die 120D and the semiconductor wafer 110W and correspond to the non-bond areas NB1. The bonding process may be similar to the process described in FIG. 1A, and thus the detailed descriptions are not repeated for simplicity. Subsequently, a second thermal treatment S54 may be performed on the polymeric material layer 130′ to form the sealing layer 130. The second thermal treatment S54 may include an annealing process conducted with a temperature in the range from about 250° C. to about 320° C., and the annealing duration in the range from about less than 10 hours. The second thermal treatment S54 may enable conversion of the polymeric material layer 130′ to be the solid and stable sealing layer 130.

In some embodiments, during the second thermal treatment S54, hydroxyl (OH) groups are bonded to the dangling bonds in the polymeric material layer 130′ by hydrolysis to form Si—OH bonds, and the hydroxyl groups may be dehydrated to form Si→O—Si bonds. A chemical reaction equation may be expressed as: SiH₂NH+2H₂O→SiO₂+NH₃+2H₂. For example, the polymeric material layer 130′ (e.g., PHPS) is converted to the sealing layer 130 (e.g., silicon oxide). The sealing layer 130 may bond the semiconductor die 120D and the semiconductor wafer 110W together and may seal the non-bond areas NB1 therebetween. As shown in FIG. 2C, the sealing layer 130 may climb upward to cover the sidewall 120WS of the semiconductor die 120D by a non-zero height 130H. The lateral dimension 130W (e.g., the width) of the sealing layer 130 measured between the boundary of the sealing layer 130 and the virtual plane on which the sidewall 120WS is located may be non-zero. In some embodiments, the lateral dimension 130W is greater than the height 130H. For example, a ratio of the lateral dimension 130W to the height 130H is about 3:1. It is realized that the ratio is an example and may be changed to other suitable values depending on product requirements.

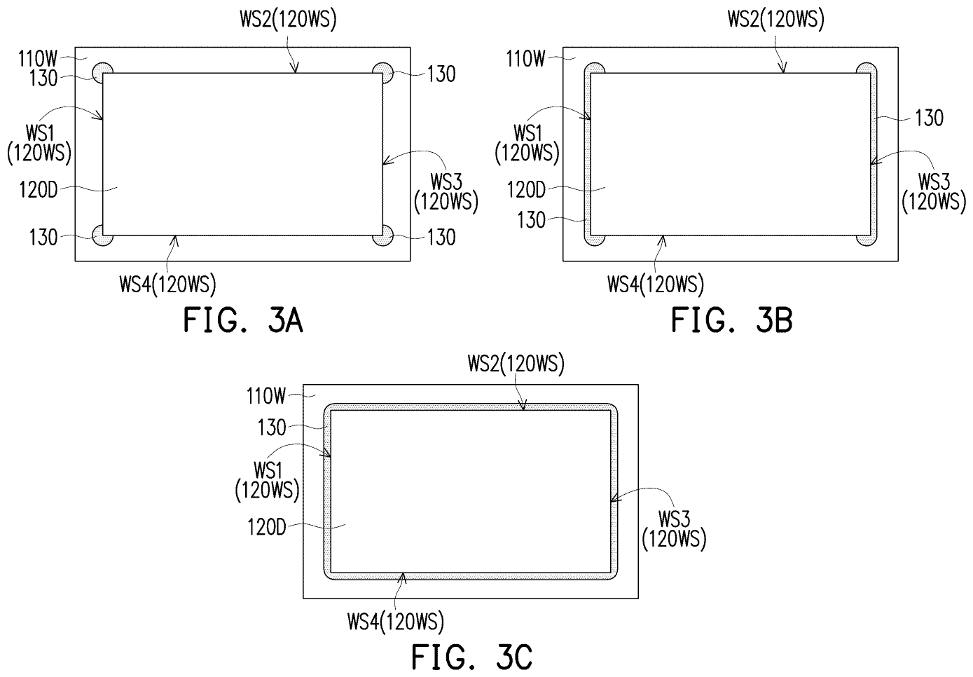

FIGS. 3A-3C are schematic top views illustrating various configurations of the bonded structure, in accordance with some embodiments. Like elements are designated with the same reference numbers for ease of understanding and the details thereof are not repeated herein. It should be noted that the top-view shapes of the semiconductor die, the semiconductor wafer, and the sealing layer are merely examples and construed no limitation in the disclosure.

Referring to FIG. 3A and with reference to the bonded structure shown in FIG. 1C or FIG. 2C, the semiconductor die 120D may include a rectangular area defined by the sidewalls 120WS (e.g., the first sidewall WS1, the second sidewall WS2, the third sidewall WS3, and the fourth sidewall WS4). The semiconductor die 120D may consist of four corners of the rectangular area as shown in the top view. The sealing layer 130 may be formed as segmented parts wrapping around the four corners of the rectangular area, respectively. In some embodiments, each of the segmented parts of the sealing layer 130 has a rounded top-view shape surrounding the corresponding corner. For example, the first segmented part covers the intersection of the first and second sidewalls (WS1 and WS2), the second segmented part covers the intersection of the second and third sidewalls (WS2 and WS3), the third segmented part covers the intersection of the third and fourth sidewalls (WS3 and WS4), and the fourth segmented part covers the intersection of the first and fourth sidewalls (WS1 and WS4).

Referring to FIG. 3B and with reference to FIG. 3A and the bonded structure shown in FIG. 1C or FIG. 2C, the configuration shown in FIG. 3B may be similar to the configuration shown in FIG. 3A, except that two opposing sidewalls (e.g., the first sidewall WS1 and the third sidewall WS3) are covered by the sealing layer 130. The other opposing sidewalls (e.g., the second sidewall WS2 and the fourth sidewall WS4) may remain unmasked by the sealing layer 130, except for the corner regions.

Referring to FIG. 3C and with reference to FIG. 3A and the bonded structure shown in FIG. 1C or FIG. 2C, the configuration shown in FIG. 3C may be similar to the configuration shown in FIG. 3B, except that the other opposing sidewalls (e.g., the second sidewall WS2 and the fourth sidewall WS4) may also be covered by the sealing layer 130. For example, the sealing layer 130 is formed as a continuous layer encircling the entire rectangular area of the semiconductor die 120D. It should be noted that the sealing layer 130 may be disposed on the bonded structure which includes non-bond areas so as to seal the non-bond areas. Combination schemes may be formed to include different types of semiconductor dies and/or sealing layer discussed herein, so that variations thereof may be carried out while still remaining within the scope of the claims and disclosure.

FIGS. 4A-4D are schematic cross-sectional views of various stages of manufacturing a semiconductor device, in accordance with some embodiments. Like elements are designated with the same reference numbers for ease of understanding and the details thereof are not repeated herein.

Referring to FIG. 4A and with reference to the bonded structure shown in FIG. 1C or FIG. 2C, an encapsulant material 140′ may be formed on the semiconductor wafer 110W to cover the semiconductor die 120D and the sealing layer 130. For example, the encapsulant material 140′ extends along the sidewalls 120WS of the semiconductor die 120D and cover the rear surface 122b of the semiconductor die 120D. The encapsulant material 140′ may include a molding compound, a molding underfill, a resin (such as epoxy), or the like, and may be formed by compression molding, transfer molding, or the like. The encapsulant material 140′ may then be cured. For example, the encapsulant material 140′ includes a polymer material and optionally includes fillers (not individually illustrated), where the fillers may be particles of silica or the like, and the polymer material may be an epoxy or the like. The fillers mixed in the polymer material may provide mechanical strength and thermal dispersion for the encapsulant material 140′. In some alternative embodiments, the encapsulant material 140′ includes silicon oxide, silicon nitride, the like, a combination thereof, etc., and may be formed through chemical vapor deposition (CVD), plasma-enhanced chemical vapor deposition (PECVD), atomic layer deposition (ALD), or the like. For example, the encapsulant material 140′ is referred to as a gap-fill oxide layer.

Referring to FIG. 4B and with reference to FIG. 4A, a planarization process (e.g., a chemical mechanical polish (CMP) process, a grinding process, an etching process, a combination thereof, or the like) may be performed on the encapsulant material 140′ to form an encapsulant 140. In some embodiments, the backside of the semiconductor die 120D is also planarized during the planarization process to form a semiconductor die 120 having a planarized surface 122b′ of the semiconductor die 120D, where the planarized surface 122b′ is accessibly exposed by the encapsulant 140. The top surface 140b of the encapsulant 140 may be substantially leveled (or coplanar) with the planarized surface 122b′ of the semiconductor die 120, within process variations.

Referring to FIG. 4C and with reference to FIG. 4B, a thinning process (e.g., a CMP process, a grinding process, an etching process, a combination thereof, or the like) may be performed on the semiconductor wafer 110 until at least a portion of the TSVs 113 is accessibly exposed. For example, the first semiconductor substrate 112 may be thinned down until the TSVs 113 are accessibly exposed by the thinned surface 112b′ of the first semiconductor substrate 112. In some embodiments, surfaces 113b of the TSVs 113 and the thinned surface 112b′ of the first semiconductor substrate 112 are substantially leveled (e.g., coplanar) with one another, within process variations.

Referring to FIG. 4D and with reference to FIG. 4C, a redistribution structure 150 with one or more layers over the thinned surface 112b′ of the first semiconductor substrate 112 and in connection with the TSVs 113. In some embodiments where the redistribution structure 150 may be formed by forming a first redistribution layer 603 over and in electrical connection with the TSVs 111. The redistribution structure 150 may include redistribution layers (RDLs) 151 (e.g., conductive lines, conductive pads, and/or conductive vias) embedded in one or more dielectric layer(s) 152. The redistribution structure 150 may be formed using any suitable methods for forming interconnect structures in integrated circuits, details are not repeated here. Once the redistribution structure 150 has been formed, conductive terminals 160 may be formed on the redistribution structure 150 and may be electrically coupled to the RDLs 151. For example, the conductive terminals 160 are electrically coupled to the semiconductor die 120D through the semiconductor wafer 110W. The conductive terminals 160 may include copper pillars, controlled collapse chip connection (C4) bumps, micro-bumps, electroless nickel-electroless palladium-immersion gold (ENEPIG) formed bumps, ball grid array (BGA) bumps, or the like.

With continued reference to FIG. 4D, a singulation process is optionally performed to dice the encapsulant 140, the semiconductor wafer 110W, and the dielectric layer 152 of the redistribution structure 150 so as to form a plurality of semiconductor devices 10. The respective semiconductor device 10 may include the first semiconductor die 110, the second semiconductor die 120 disposed on and bonded to the first semiconductor die 110, the sealing layer 130 sealing the non-bonded areas of the first and second semiconductor dies (110 and 120), the encapsulant 140 disposed on the first semiconductor die 110 and laterally covering the second semiconductor die 120 and the sealing layer 130, the redistribution structure 150 formed on the first semiconductor die 110 and opposite to the second semiconductor die 120, and the conductive terminals 160 formed on the redistribution structure 150 and electrically coupled to the second semiconductor die 120 through the redistribution structure 150 and the first semiconductor die 110.

The sealing layer 130 may be formed by: forming the polysilazane-based dielectric material in the non-bond area or on the predetermined area; volatilizing the solvent in the polysilazane-based dielectric material; optionally performing the plasma treatment to form dangling bonds in the polysilazane-based dielectric material, performing a thermal treatment on the polysilazane-based dielectric material to form the sealing layer 130. For example, the polysilazane-based dielectric material reacts with water in the air to cause hydrolysis reaction, thereby forming the silicon oxide layer. The hydrolysis reaction that forms the sealing layer 130 may use a process temperature of about room temperature (e.g., about 22° C. to about 24° C.).

In some embodiments where the bonding dielectric layer 1281 of the second bonding structure 128 and/or the bonding dielectric layer 1181 of the first bonding structure 118 is/are made of silicon oxide, no visible interface is formed between the sealing layer 130 (e.g., the silicon oxide layer) and the bonding dielectric layer(s) (1281 and/or 1181). Therefore, in FIG. 4D, the interface between the sealing layer 130 and the bonding dielectric layers (1281 and 1181) are illustrated in the dashed lines to indicate it may (or may not) exist. The bonding strength of the first and second semiconductor dies (110 and 120) may be increased by forming the sealing layer 130 between the first and second semiconductor dies (110 and 120) since more oxide-to-oxide bonds are formed among the sealing layer 130 and the first and second semiconductor dies (110 and 120). The sealing layer 130 may seal the non-bond areas of the first and second semiconductor dies (110 and 120). This may prevent the bonding interface from delaminating and prevent any cracks (from, e.g., thermal mismatch stresses) that do form from extending into the functional region. Such protection may help provide robust bonding between the first and second semiconductor dies (110 and 120), and the reliability of the semiconductor device 10 may be improved.

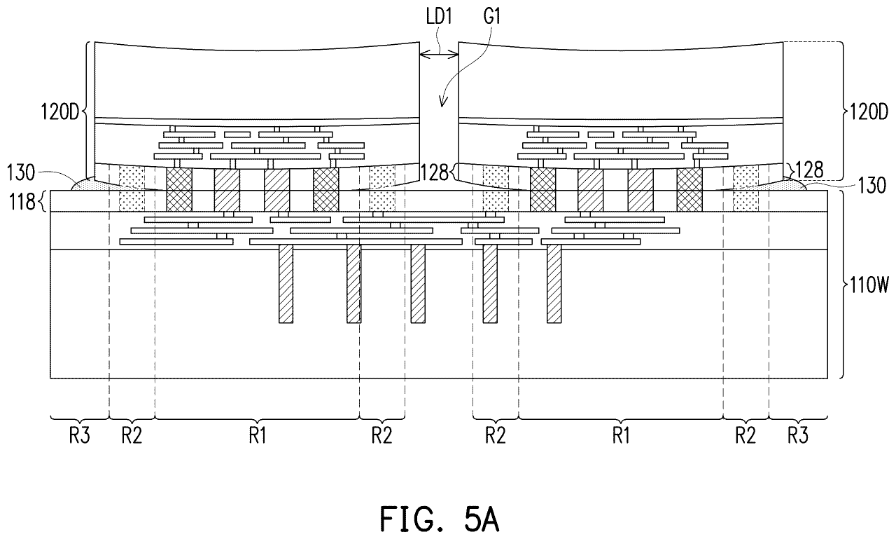

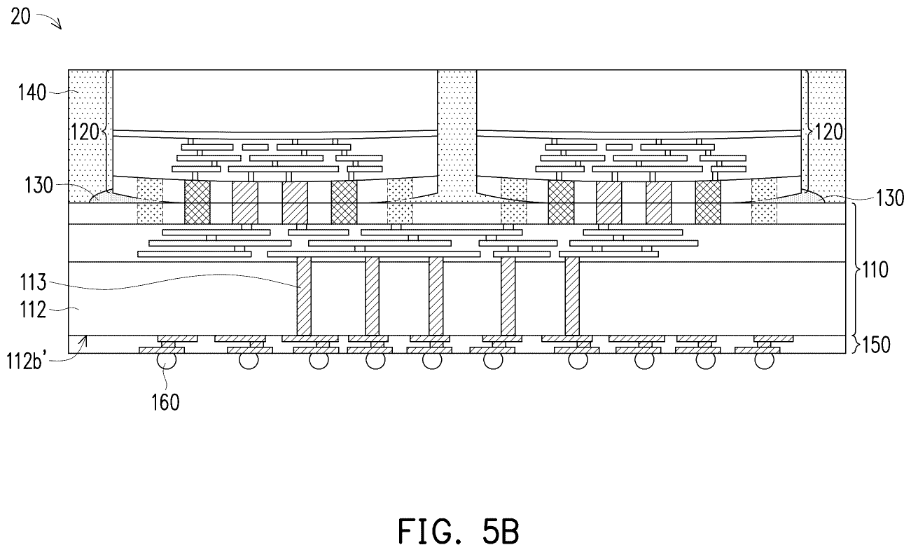

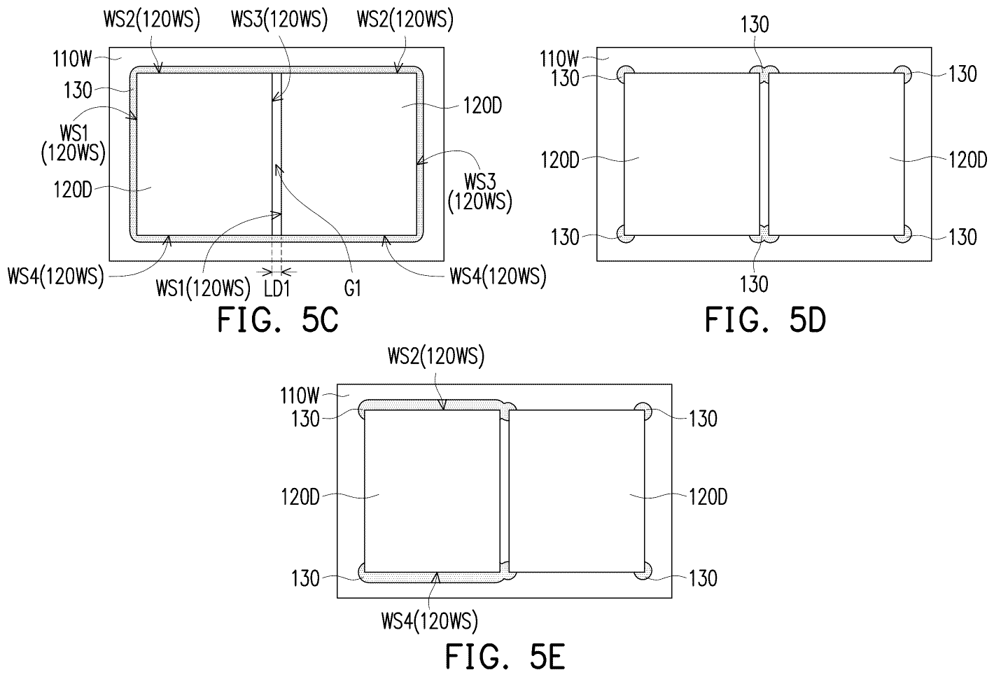

FIGS. 5A-5B are schematic cross-sectional views of various stages of manufacturing a semiconductor device, and FIGS. 5C-5E are schematic top views illustrating various configurations of the structure shown in FIG. 5A, in accordance with some embodiments. Like elements are designated with the same reference numbers for ease of understanding and the details thereof are not repeated herein. Unless specified otherwise, the materials and the formation methods of the components in these embodiments are essentially the same as the like components, which are denoted by like reference numerals in the embodiments shown in FIGS. 1A-1C, 2A-2C, and 4A-4D.

Referring to FIG. 5A and with reference to the bonded structure shown in FIG. 1C or FIG. 2C, a plurality of semiconductor dies 120D may be disposed on and bonded to the semiconductor wafer 110W. The respective semiconductor die 120D and the semiconductor wafer 110W may be similar to the semiconductor die 120D and the semiconductor wafer 110W described in FIG. 1A, respectively. In some embodiments, the semiconductor dies 120D are of different sizes. In some embodiments, the semiconductor dies 120D may have a same shape and a same size. After placing the semiconductor dies 120D on the semiconductor wafer 110W, a gap G1 may be formed between adjacent two of the semiconductor dies 120D. For example, a lateral dimension LD1 of the gap G1 between two adjacent sidewalls of the semiconductor dies 120D is non-zero. It should be noted that although two semiconductor dies 120D are illustrated, more than two semiconductor dies 120D having the same/different sizes or functions may be bonded to the semiconductor wafer 110W, depending on product requirements.

With continued reference to FIG. 5A, the second bonding structure 128 of the respective semiconductor die 120D is bonded to the first bonding structure 118 of the semiconductor wafer 110W. The bonding process of the semiconductor dies 120D and the semiconductor wafer 110W may be similar to the process described in FIG. 1A, and thus the detailed descriptions are not repeated for simplicity. The sealing layer 130 may then be formed to fill the non-bond areas of the semiconductor dies 120D and the semiconductor wafer 110W. For example, after the bonding process, non-bond areas exist at the bonding interface and in the peripheral region R3 (or both of the peripheral region R3 and the buffer region R2). The sealing layer 130 may extend from the peripheral region R3 toward the buffer region R2. The forming process of the sealing layer 130 may be performed before or after the bonding process. The formation of the sealing layer 130 may be similar to the processes described in FIGS. 1B-1C or FIGS. 2A-2C, and thus the detailed descriptions are not repeated for simplicity.

Referring to FIG. 5C and with reference to FIG. 5A, the respective semiconductor die 120D may include a rectangular area defined by the sidewalls 120WS (e.g., the first sidewall WS1, the second sidewall WS2, the third sidewall WS3, and the fourth sidewall WS4). The sealing layer 130 may be formed as a continuous layer encircling the boundary of the array of the semiconductor dies 120D. In some embodiments, the lateral dimension LD1 is not wide enough, so that the dispensing tool may not be positioned in the gap G1. Therefore, the sealing layer 130 may not be formed in the gap G1 between two adjacent semiconductor dies 120D. For example, the sidewalls of the adjacent semiconductor dies 120D facing each other and in the gap G1 are exposed by the sealing layer 130. In the illustrated embodiment, the third sidewall WS3 of the semiconductor die 120D on the left hand side of the top view and the first sidewall WS1 of the semiconductor die 120D on the right hand side of the top view are not covered by the sealing layer 130. In alternative embodiments where the lateral dimension LD1 is wide enough, the sealing layer 130 encircles each sidewall of the respective semiconductor die 120D.

Referring to FIG. 5D and with reference to FIG. 3A, the configuration shown in FIG. 5D may be similar to the configuration shown in FIG. 3A, except that two semiconductor dies 120D are bonded to the semiconductor wafer 110W, and the sealing layer 130 formed as the segmented parts may be merged together at the adjacent corners of the semiconductor dies 120D. Referring to FIG. 5E and with reference to FIG. 5D, the configuration shown in FIG. 5E may be similar to the configuration shown in FIG. 5D, except that two opposing sidewalls (e.g., the second sidewall WS2 and the fourth sidewall WS4) of the semiconductor die on the left hand side of the top view are covered by the sealing layer 130. It should be noted that the sealing layer 130 may be disposed on the bonded structure which include non-bond areas so as to seal the non-bond areas. Combination schemes may be formed to include different types of semiconductor dies and/or sealing layer discussed herein, so that variations thereof may be carried out while still remaining within the scope of the claims and disclosure.

Referring back to FIG. 5B and with reference to FIG. 5A and FIGS. 4A-4D, the encapsulant 140 may be formed on the semiconductor wafer 110W and laterally cover the sealing layer 130 and the semiconductor dies 120D. In some embodiments, the encapsulant 140 fills the gap G1 between the two adjacent semiconductor dies 120D. The material and the forming method of the encapsulant 140 may be similar to those of the encapsulant 140 described in FIGS. 4A-4B, and thus the detailed descriptions are not repeated for simplicity. Next, the semiconductor wafer 110W may be thinned down to expose the TSVs 113 for further electrical connections. The backside thinning process of the semiconductor wafer 110W may be similar to the process described in FIG. 4C, and thus the detailed descriptions are not repeated for simplicity. Next, the redistribution structure 150 may be formed on the thinned surface 112b′ of the first semiconductor substrate 112 and electrically coupled to the TSVs 113. The conductive terminals 160 may then be formed on the redistribution structure 150 and electrically coupled to the semiconductor die 120D through the semiconductor wafer 110W. The formation of the redistribution structure 150 and the conductive terminals 160 may be similar to the processes described in FIG. 4D, and thus the detailed descriptions are not repeated for simplicity.

With continued reference to FIG. 5B and FIG. 4D, a singulation process is optionally performed to dice the encapsulant 140, the semiconductor wafer 110W, and the redistribution structure 150 so as to form a plurality of semiconductor devices 20. The semiconductor device 20 is similar to the semiconductor device 10 described in FIG. 4D, except that the number of the semiconductor dies 120 and the configuration of the sealing layer 130. The sealing layer 130 may be formed by converting the polysilazane-based material to the silicon oxide layer. By sealing the non-bond areas of the first and second semiconductor dies (110 and 120) using the sealing layer 130, the bonding strength of the first and second semiconductor dies (110 and 120) may be increased. The sealing layer 130 may have the function of relieving stress, and the stress applied by the encapsulant 140 may be relieved. The sealing layer 130 may also help to block cracks (from, e.g., thermal mismatch stresses) from extending into the functional region. Such protection may help provide robust bonding between the first and second semiconductor dies (110 and 120) and improve the reliability of the semiconductor device 20.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor device includes a first semiconductor die, a second semiconductor die bonded to the first semiconductor die, a sealing layer, and an encapsulant disposed on the first semiconductor die and laterally covering the sealing layer and the second semiconductor die. The second semiconductor die is bent with an edge of the second semiconductor die curving upwardly, where a non-bond area is at a periphery of a bonding interface of the first and second semiconductor dies. The sealing layer seals the non-bond area of the first and second semiconductor dies.

According to some embodiments, a semiconductor device includes a bottom die, a top die disposed on the bottom die, a sealing layer joined to the top and bottom dies, an encapsulant disposed on the bottom die and covering the sealing layer and the top die. The top die includes a bonding structure bonded to the bottom die. The bonding structure includes a functional region, a peripheral region surrounding the functional region, and a buffer region between the functional region and the peripheral region. The sealing layer extends from a sidewall of the top die to the peripheral region and further into the buffer region and is stopped at the buffer region.

According to some embodiments, a manufacturing method of a semiconductor device includes: bonding a top die to a bottom die; forming a sealing layer to seal a non-bond area of the top die and the bottom die; and forming an encapsulant on the bottom die to cover the sealing layer and the top die. Forming the sealing layer includes: forming a polysilazane-based dielectric material; and performing a thermal treatment on the polysilazane-based dielectric material to convert the polysilazane-based dielectric material to the sealing layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first semiconductor die;
a second semiconductor die bonded to the first semiconductor die, the second semiconductor die bent with an edge of the second semiconductor die curving upwardly, wherein a non-bond area is at a periphery of a bonding interface of the first and second semiconductor dies;
a sealing layer sealing the non-bond area of the first and second semiconductor dies; and
an encapsulant disposed on the first semiconductor die and laterally covering the sealing layer and the second semiconductor die.

2. The semiconductor device of claim 1, wherein:
the second semiconductor die comprises a functional region and a buffer region between the functional region and the edge of the second semiconductor die,
the non-bond area is in the buffer region and the sealing layer covers the buffer region.

3. The semiconductor device of claim 1, wherein the second semiconductor die further comprises a dummy conductive connector in the non-bond area, and the sealing layer is in contact with the dummy conductive connector.

4. The semiconductor device of claim 1, wherein the sealing layer comprises a curved surface connecting a sidewall of the second semiconductor die and a top surface of the first semiconductor die in a cross-sectional view.

5. The semiconductor device of claim 1, wherein the sealing layer comprises a height and a lateral dimension greater than the height.

6. The semiconductor device of claim 1, wherein the sealing layer at least wraps around corners of the second semiconductor die.

7. The semiconductor device of claim 1, wherein:
the first semiconductor die comprises a semiconductor substrate, an interconnect structure over the semiconductor substrate, and a bonding structure over the interconnect structure and bonded to the second semiconductor die,
the bonding structure comprises a bonding dielectric layer and bonding connectors electrically coupled to the interconnect structure, and
bonding surfaces of the bonding dielectric layer and the bonding connectors are substantially coplanar.

8. The semiconductor device of claim 7, wherein the sealing layer and the bonding dielectric layer of the first semiconductor die are formed of a same material.

9. The semiconductor device of claim 1, wherein:
each of the first and second semiconductor dies comprises a bonding structure,
the bonding structure comprises a bonding dielectric layer and bonding connectors laterally covered by the bonding dielectric layer, and
the sealing layer fused to a portion of the bonding dielectric layers of the first and second semiconductor dies.

10. A semiconductor device, comprising:
a bottom die;
a top die disposed on the bottom die, the top die comprising a bonding structure bonded to the bottom die, the bonding structure comprising a functional region, a peripheral region surrounding the functional region, and a buffer region between the functional region and the peripheral region;
a sealing layer joined to the top and bottom dies, the sealing layer extending from a sidewall of the top die to the peripheral region and further into and stopped at the buffer region; and
an encapsulant disposed on the bottom die and covering the sealing layer and the top die.

11. The semiconductor device of claim 10, wherein the functional region of the top die is lower than the peripheral region of the top die, relative to a bonding surface of the bottom die.

12. The semiconductor device of claim 10, wherein a vertical gap is between the bottom die and the peripheral region of the top die, and the sealing layer fills the vertical gap.

13. The semiconductor device of claim 10, wherein metal-to-dielectric bonds are formed at an interface of the sealing layer and the bonding structure of the top die.

14. The semiconductor device of claim 10, wherein a coverage area of the sealing layer on the bottom die is greater than a coverage area of the sealing layer on a sidewall of the top die.

15. The semiconductor device of claim 10, wherein the sealing layer comprises a convex curved surface connecting a sidewall of the top die and a top surface of the bottom die in a cross-sectional view.

16. A manufacturing method of a semiconductor device, comprising:
bonding a top die to a bottom die;
forming a sealing layer to seal a non-bond area of the top die and the bottom die, wherein forming the sealing layer comprises:
forming a polysilazane-based dielectric material; and
performing a thermal treatment on the polysilazane-based dielectric material to convert the polysilazane-based dielectric material to the sealing layer; and
forming an encapsulant on the bottom die to cover the sealing layer and the top die.

17. The manufacturing method of claim 16, wherein the polysilazane-based dielectric material is formed on the bottom die before bonding the top die to the bottom die.

18. The manufacturing method of claim 16, wherein forming the sealing layer further comprises:
performing a plasma treatment on the polysilazane-based dielectric material to form dangling bonds in the polysilazane-based dielectric material.

19. The manufacturing method of claim 16, wherein forming the sealing layer further comprises:
volatilizing a solvent in the polysilazane-based dielectric material before performing the thermal treatment.

20. The manufacturing method of claim 16, wherein forming the sealing layer further comprises:
converting the polysilazane-based dielectric material to a silicon oxide layer by a hydrolysis reaction.
